(19) United States
(12) Patent Application Publication
(10) Pub. No.: US 2025/0159842 A1
(43) Pub. Date: May 15, 2025

(54) THERMAL CONTROL DEVICE, IN PARTICULAR FOR A MOTOR VEHICLE, AND ASSOCIATED THERMAL CONTROL UNIT

(71) Applicant: VALEO SYSTEMES THERMIQUES, Le Mesnil-Saint-Denis (FR)

(72) Inventors: Moussa Nacer Bey, Le Mesnil-Saint-Denis (FR); Kamel Azzouz, Le Mesnil-Saint-Denis (FR); Julien Tissot, Le Mesnil-Saint-Denis (FR); Jeremy Blandin, Le Mesnil-Saint-Denis (FR); Julio Guerra, Le Mesnil-Saint-Denis (FR)

(73) Assignee: VALEO SYSTEMES THERMIQUES, Le Mesnil-Saint-Denis (FR)

(21) Appl. No.: 18/728,456

(22) PCT Filed: Jan. 12, 2023
(86) PCT No.: PCT/EP2023/050640

§ 371 Date: Jul. 12, 2024

(30) Foreign Application Priority Data
Jan. 14, 2022 (FR) FR2200316

(51) Int. Cl. H05K 7/20; H01M 10/613; H01M 10/625; H01M 10/6569

(52) U.S. Cl. CPC H05K 7/20345; H01M 10/613; H01M 10/625; H01M 10/6569; H05K 7/20936

(57) ABSTRACT

A thermal control device for at least one module for a motor vehicle includes a dielectric fluid circuit and a number of nozzles for spraying dielectric fluid and configured to be arranged to wet at least one surface of the at least one module with dielectric fluid. The spray nozzles are configured to project, via at least one projection orifice, a fan shaped jet of dielectric fluid. The spray nozzles each include a projection channel configured to direct the dielectric fluid and at least one dielectric fluid deflector onto which the projection channel opens, to orient the dielectric fluid to create a fan shaped jet.

The present invention relates to a device for thermal control of electrical and/or electronic components liable to release heat during operation, in particular in the automotive field. The invention also relates to a thermal control unit comprising such a device.

The components liable to be affected by the present invention may be electrical energy storage devices, in particular battery elements or power electronics, for example but not limitatively semi-conductors such as diodes or transistors. They could also be components of computer servers.

The invention is advantageously applied in the field of devices for thermal control of a power electronics module or device, i.e. comprising power electronics components. In operation, the temperature of such a power electronics device or module may rise, with the risk of damage to some of the power electronics components.

The invention is also advantageously applicable in the field of devices for thermal control of electrical energy storage elements, such as a battery assembly or pack for motor vehicles with electric and/or hybrid drive. The electrical energy for electric and/or hybrid vehicles is supplied by one or more batteries. During operation, electrical energy storage elements such as batteries heat up and thus risk being damaged. In particular, a charging technique, referred to as rapid charging, consists of charging the energy storage elements at a high voltage and high amperage for a short time, in particular a maximum time of about twenty minutes. Such rapid charging causes the electrical energy storage elements to heat up significantly, something which needs to be managed.

In the field of motor vehicles, it is known to use a thermal control device in particular for cooling components, e.g. for electrical energy storage, such as batteries. Such a thermal control device makes it possible to modify a temperature of an electrical energy storage device either during starting of the vehicle in cold weather by increasing its temperature for example, or during travel or an operation of recharging said system by decreasing the temperature of the battery elements which tend to heat up when they are being used.

According to a known solution, the thermal control device comprises a cold plate inside which a cooling fluid circulates and which is arranged in contact with the components to be cooled. It has been found that such an arrangement may lead to non-uniform cooling of the components of one and the same device, e.g. for electrical energy storage, leading to a decrease in the overall performance These thermal control devices also have high thermal resistance because of the thicknesses of material present between the cooling fluid and the elements to be cooled. Furthermore, this solution generally takes up considerable space.

According to another known thermal control solution, in particular for cooling components such as battery elements, a dielectric fluid is projected, generally in the form of a conical spray or jet, directly onto the components via a dielectric fluid circuit and orifices for spraying dielectric fluid. A heat exchange may then take place between the components and the dielectric fluid which comes into direct contact with a surface of the components.

However, under operating conditions, components such as battery elements-once installed in the motor vehicle-are not necessarily arranged flat and parallel to the horizontal, but may be sloping relative to the horizontal. It has then been found that the dielectric fluid is not sprayed uniformly relative to the surface of the components to be wetted, even when these components are only slightly sloping. The result is thermal control, in particular cooling, which is not uniform, substantially on the side where the component is sloping. The zones of the components receiving little or no spray may then be subject to local overheating, with poor thermal homogeneity of the components.

One solution may be to increase the number of nozzles. However, another problem arises because of restricted space. It is therefore necessary to limit the number of clements, in particular the spray nozzles, of the thermal control device as far as possible.

The object of the present invention is to at least partially remedy one or more of said drawbacks by proposing a thermal control device allowing homogenous atomization of the dielectric fluid in order to avoid an imbalance in the thermal control, such as cooling, of the components irrespective of the installation of the device to be regulated, in particular even when the components are sloping relative to the horizontal.

To this end, the invention relates to a thermal control device for at least one module comprising at least one electronic and/or electrical component, in particular for a motor vehicle, said device comprising a dielectric fluid circuit and a predefined number of nozzles for spraying dielectric fluid and configured to be arranged so as to wet at least one surface of said at least one module with dielectric fluid.

Here, a module may be an energy storage cell. As a variant, a module may comprise multiple energy storage cells. A module may also be defined as a container or housing containing one or more electronic and/or electrical components. The module may be closed. It may be a group of cells, for example in an element forming a cover or hood over an upper part of a battery pack or assembly.

According to the invention, the spray nozzles are configured to project, via at least one projection orifice, a generally fan-shaped or generally flat jet of dielectric fluid, i.e. delimited by two main directions.

Such a generally fan-shaped jet of dielectric fluid, also called a flat jet, intended to be projected by a nozzle, has a spread which is wider than in the solutions of the prior art, allowing spraying of a larger surface area of the modules to be thermally controlled irrespective of the slope or location where the modules are installed. Thus the dielectric fluid may be sprayed uniformly, resulting in a thermal control, in particular cooling, of the modules which is more homogenous than in the solutions of the prior art.

The thermal control device may also have one or more of the following features described below, considered separately or in combination.

Advantageously, the projection orifice may be formed by a projection slot. This may provide or contribute to the flat form of the dielectric fluid jet to be projected by the nozzle.

The projection slot is for example generally oval in form.

According to an embodiment, the spray nozzles each comprise a projection channel in which the dielectric fluid is intended to flow. The nozzles may also comprise at least one dielectric fluid deflector onto which the projection channel opens, so as to orient the dielectric fluid in order to create the generally flat jet.

The projection channel mainly extends along a longitudinal axis. The deflector may comprise a wall inclined relative to the longitudinal axis of the projection channel. The inclined wall extends so as to form an obstacle facing an outlet of the projection channel.

The inclined wall of the deflector forms an angle for example between 105° and 130° with the longitudinal axis of the projection channel.

According to another aspect, the inclined wall of the deflector extends over a height which increases along an axis transverse to the longitudinal axis of the projection channel. The inclined wall of the deflector may extend up to a maximum height of at least half the height of the projection channel. Preferably, the maximum height is at most 150% of the height of the projection channel.

The generally fan-shaped or flat jet of dielectric fluid intended to be projected by a nozzle may define an opening angle greater than 90°, in particular between 100° and 180°, preferably of the order of 170°.

At least some spray nozzles may have a single projection orifice so as to project a single jet of dielectric fluid.

As a variant or in addition, at least some spray nozzles may have at least two projection orifices so as to project at least two separate jets of dielectric fluid.

One or more spray nozzles may be arranged in series along the dielectric fluid circuit.

The thermal control device may comprise at least two series of spray nozzles. Each series may comprise at least one spray nozzle.

The dielectric fluid circuit may comprise at least two parallel pipes for supply of the two series of spray nozzles.

The invention also relates to a thermal control unit. This unit may be intended to be installed in a vehicle, notably a motor vehicle.

The thermal control unit comprises at least one module containing at least one electronic and/or electrical component, and at least one device for thermal control of said at least one module as described above.

The module may be an electrical energy storage module.

Advantageously, the spray nozzles are configured to project at least one generally fan-shaped or flat jet of dielectric fluid parallel to a plane defined by a surface of said at least one module.

The thermal control unit may comprise a plurality of modules. In this case, the thermal control unit comprises at least one spray nozzle arranged facing a space between two adjacent modules

Such a spray nozzle may be arranged facing a space between the opposing longitudinal or lateral edges of two adjacent modules.

At least one spray nozzle may be arranged centrally relative to the two adjacent modules. Such a spray nozzle is in particular arranged centrally relative to the opposing edges of the two adjacent modules.

Alternatively or additionally, at least one spray nozzle may be arranged facing a space between at least two opposing tips of two adjacent modules.

The thermal control unit may comprise at least one row of modules. Furthermore, the control device may comprise at least one series of nozzles associated with the row of modules, said series comprising at least one spray nozzle.

In an exemplary embodiment, the thermal control unit may comprise at least two rows of modules. The two rows of modules may be arranged parallel with one another.

The control device may comprise one or more nozzles arranged between two rows of modules.

According to another aspect, the thermal control unit may comprise a housing containing said at least one module.

The module or modules may have a lower face arranged against a bottom of the housing and an opposite upper face. At least one nozzle may be arranged facing the upper face of at least one module.

At least one spray nozzle may be arranged facing a space between said at least one module and a wall of the housing. This spray nozzle may be arranged centrally relative to an edge of said at least one module facing the housing wall. As a variant, this spray nozzle may be arranged facing a space between a tip of said at least one module and the housing wall.

Furthermore, such a spray nozzle arranged between said at least one module and a housing wall may be configured to project at least one generally flat jet of dielectric fluid parallel to a plane defined by the surface of said at least one module facing the housing wall.

According to an embodiment, the thermal control device may comprise at least two groups of spray nozzles arranged such that the spray nozzles of a first group are oriented so as to project at least one dielectric fluid jet in a first direction, and the spray nozzles of a second group are oriented so as to project at least one dielectric fluid jet in a second direction opposite the first direction.

Also, the thermal control unit may comprise at least one row of modules on which at least two series of spray nozzles are arranged.

As a variant, the thermal control unit may comprise at least two rows of modules, on each of which at least two series of spray nozzles are arranged. At least a third series of nozzles may be arranged between the two rows of modules.

Also, a spray nozzle may be fluidically connected to a distribution point of the dielectric fluid circuit. Such a spray nozzle may be configured to project a single dielectric fluid jet or multiple dielectric fluid jets.

As an alternative, at least two spray nozzles may be connected to a common distribution point of the dielectric fluid circuit, each spray nozzle being configured to project a single dielectric fluid jet or multiple dielectric fluid jets. The spray nozzles are advantageously oriented so as to project complementary jets of dielectric fluid in order to optimize the wetting of the surface of said at least one module.

The invention may also concern a battery pack comprising a plurality of energy storage cells and at least one thermal control device as defined above, comprising a dielectric fluid circuit and a predefined number of dielectric fluid spray nozzles arranged so as to wet the plurality of energy storage cells.

Further advantages and features of the invention will become more clearly apparent from reading the following description, provided by way of illustrative and non-limiting example, and the appended drawings, in which:

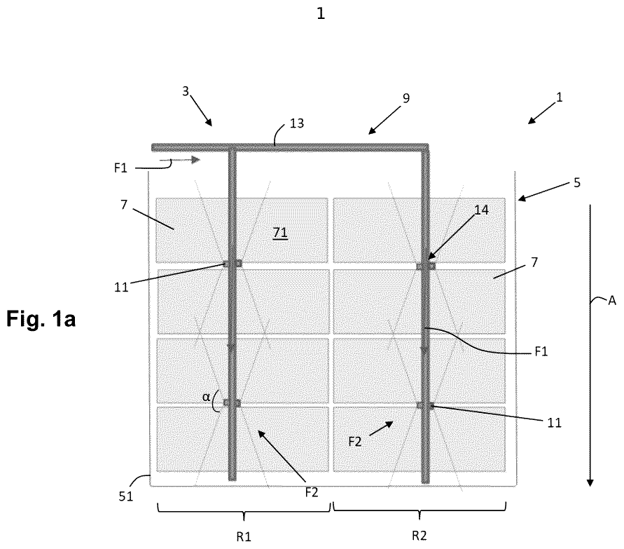

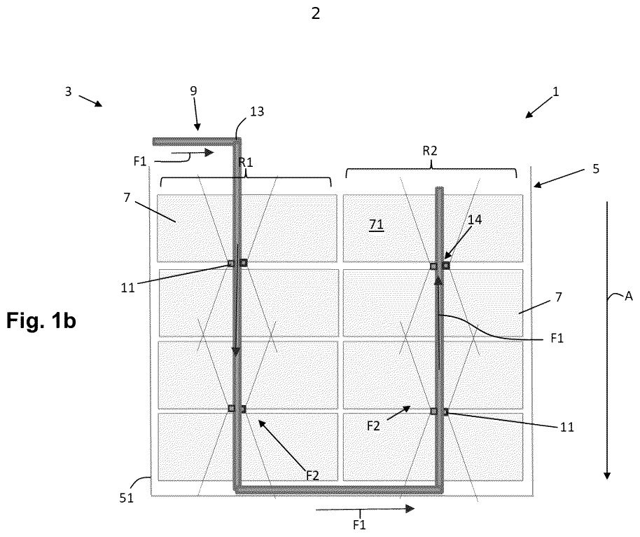

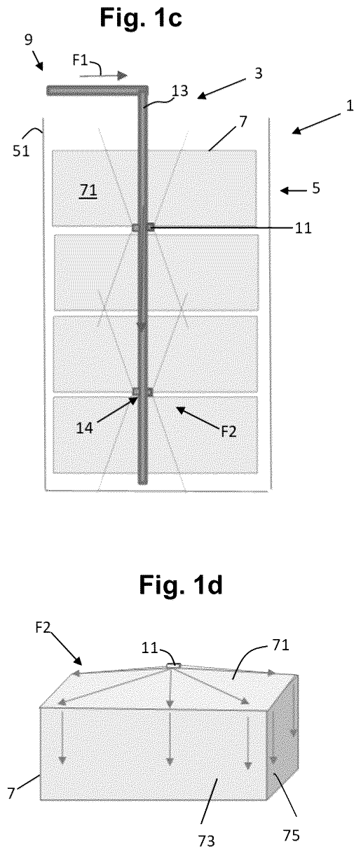

FIG. 1a, FIG. 1b, FIG. 1c schematically illustrate a thermal control unit comprising modules to be thermally controlled, and a thermal control device comprising a dielectric fluid circuit and nozzles arranged according to different variants of a first configuration.

FIG. 1d is a perspective view of a module to be thermally controlled and an exemplary arrangement of a nozzle according to the first configuration.

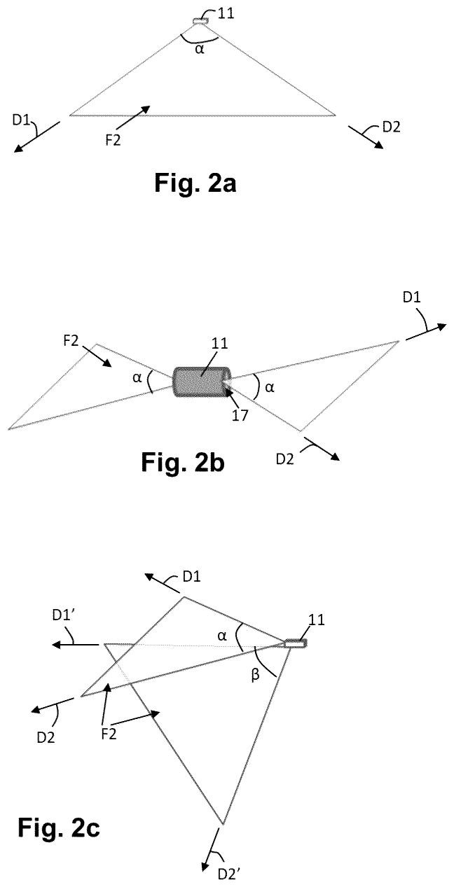

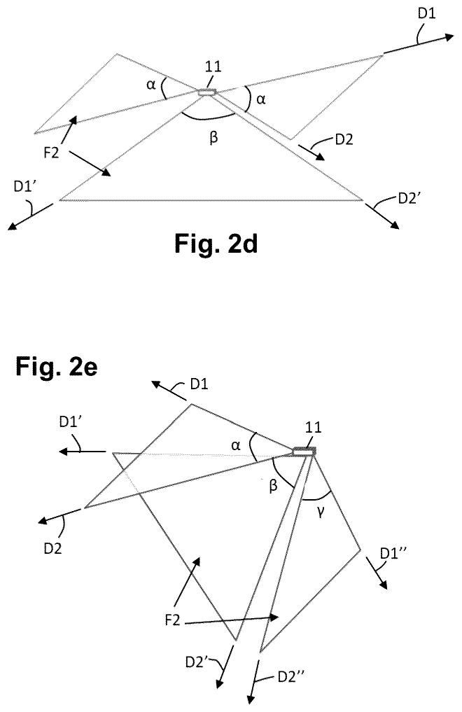

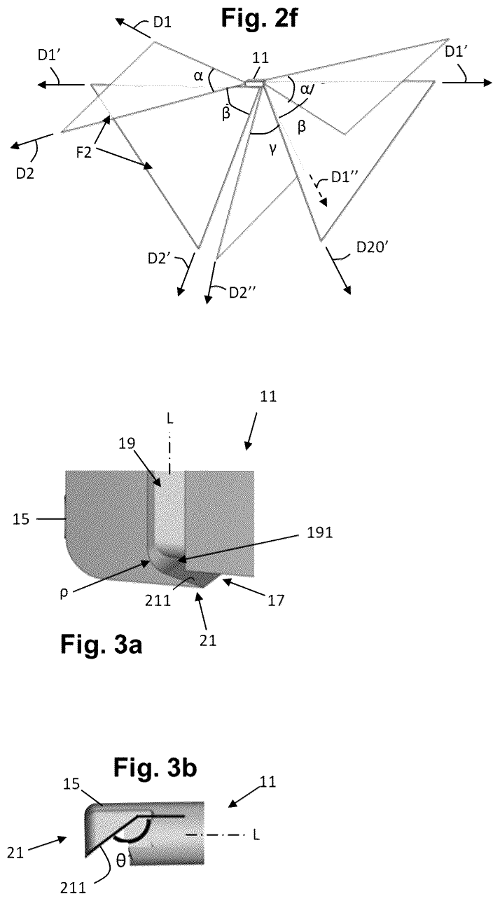

FIG. 2a is an exemplary embodiment of a nozzle configured to project a generally flat jet of dielectric fluid.

FIG. 2b is an exemplary embodiment of a nozzle configured to project two jets of dielectric fluid in mirror symmetry.

FIG. 2c is an exemplary embodiment of a nozzle configured to project two jets of dielectric fluid in intersecting planes.

FIG. 2b is an exemplary embodiment of a nozzle configured to project three jets of dielectric fluid, two of which are in mirror symmetry.

FIG. 2e is an exemplary embodiment of a nozzle configured to project three jets of dielectric fluid in intersecting planes.

FIG. 2f is an exemplary embodiment of a nozzle configured to project four jets of dielectric fluid in different planes.

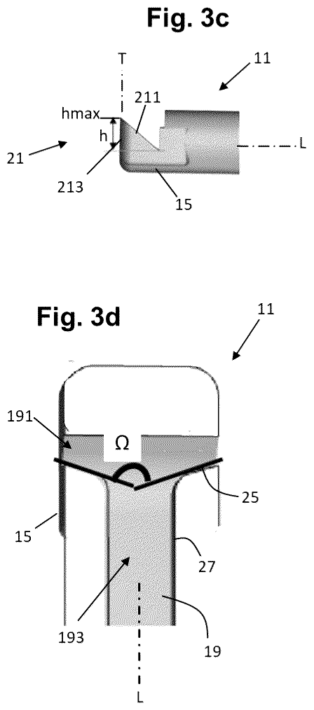

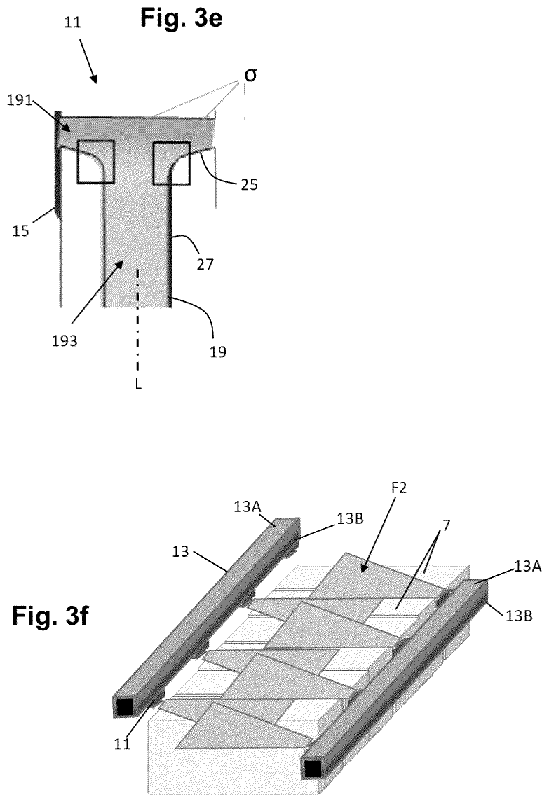

FIG. 3a shows a sectional, perspective view of an exemplary embodiment of a nozzle, the nozzle head of which comprises a deflector.

FIG. 3b and FIG. 3c are side views of the nozzle head from FIG. 3a.

FIG. 3d and FIG. 3e are sectional plan views of the nozzle head from FIG. 3a.

FIG. 3f illustrates schematically a set of modules to be thermally controlled and pipes of the dielectric fluid circuit integrating the nozzles.

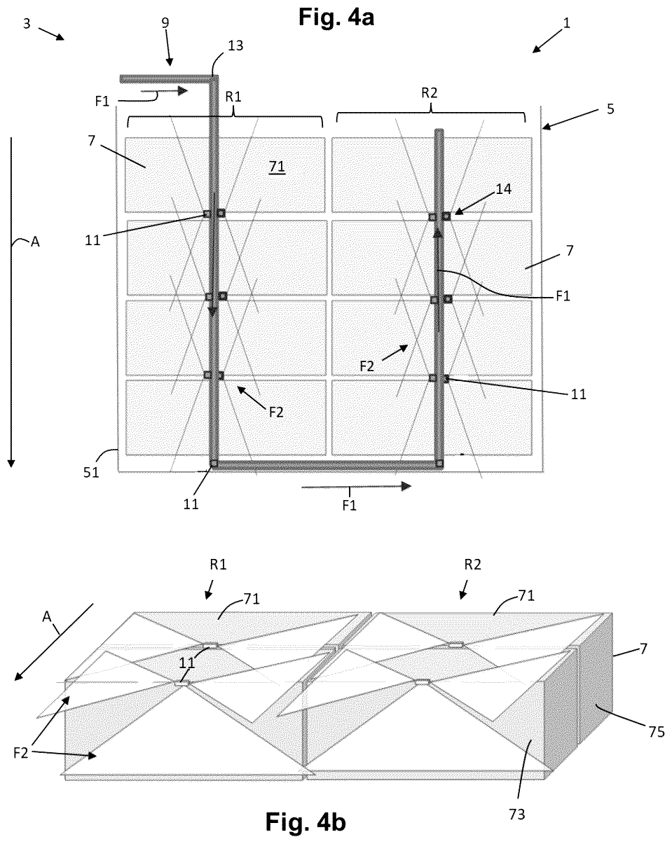

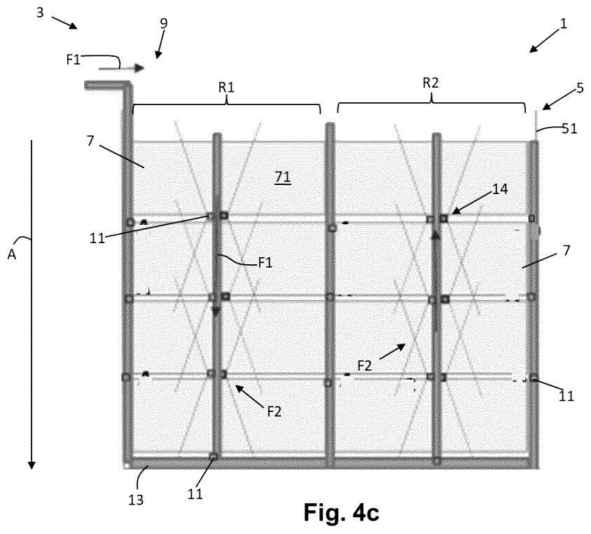

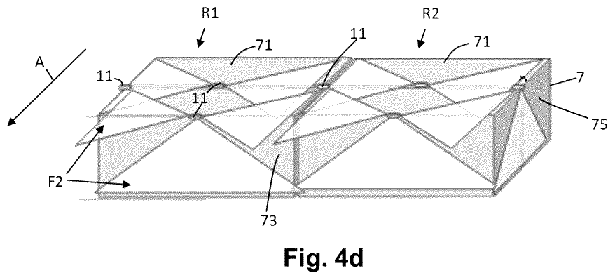

FIG. 4a, FIG. 4b, FIG. 4c, FIG. 4d illustrate schematically the thermal control unit in which the nozzles are arranged according to different variants of a second configuration.

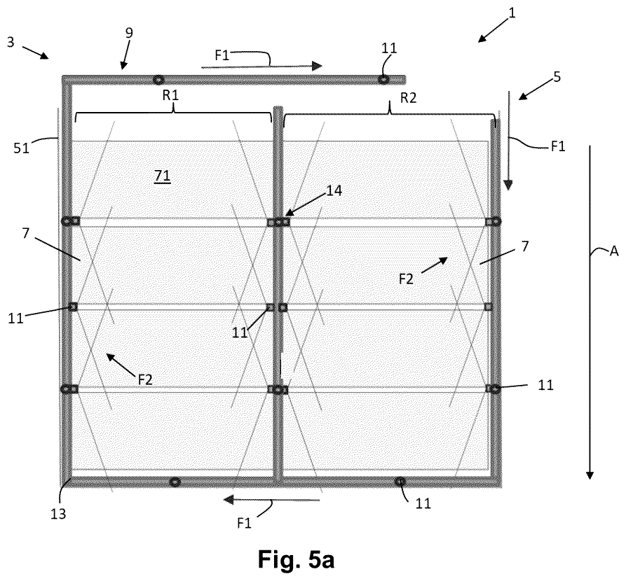

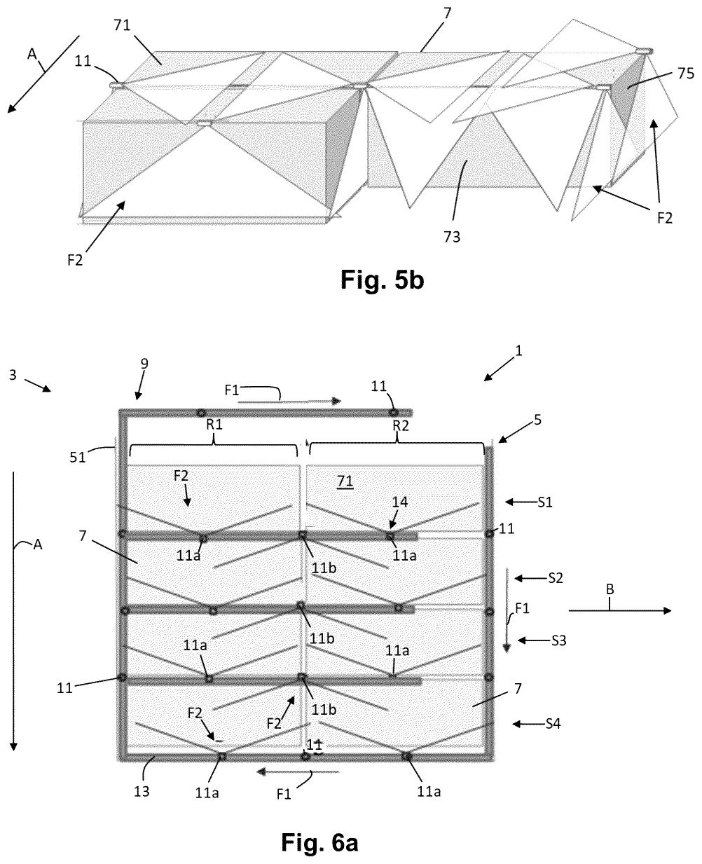

FIG. 5a and FIG. 5b illustrate schematically the thermal control unit in which the nozzles are arranged according to a third configuration.

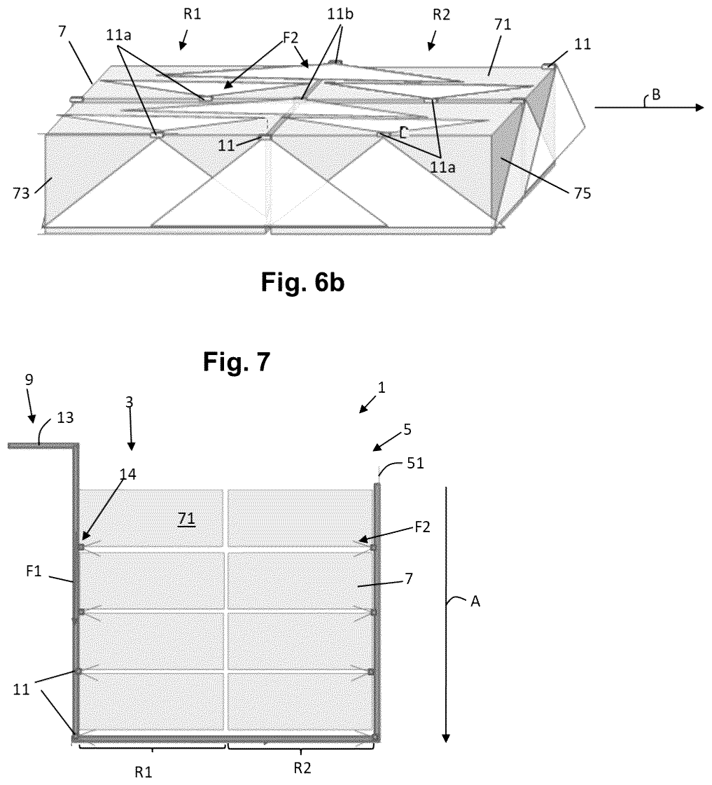

FIG. 6a and FIG. 6b illustrate schematically the thermal control unit in which the nozzles are arranged according to a fourth configuration.

FIG. 7 illustrates schematically the thermal control unit in which the nozzles are arranged according to a fifth configuration.

In these figures, identical elements have been designated by the same reference numbers.

The following embodiments are examples. Although the description refers to one or more embodiments, this does not necessarily mean that each reference sign relates to the same embodiment, or that the features only apply to a single embodiment. Individual features of different embodiments can also be combined or interchanged to provide other embodiments.

In the description, certain elements may be indexed, for example first element or second element. In this case, the ordinal number serves simply to differentiate and denote elements that are similar but not identical. This numbering does not imply that one element takes priority over another and such designations can easily be interchanged without departing from the scope of the present description. Likewise, this numbering does not imply any chronological order.

FIG. 1a shows schematically an embodiment of a thermal control unit 1 which may be intended to be installed in a vehicle, in particular a motor vehicle.

The thermal control unit 1 comprises at least one thermal control device 3, described in more detail below.

The thermal control unit 1 may also comprise a device 5 to be thermally controlled, such as an electrical storage device 5, comprising one or more electrical or electronic components of which the temperature must be regulated, e.g. reduced. More precisely, the device 5 comprises one or more modules 7, in particular for electrical storage, comprising the electronic and/or electrical component or components. In the embodiment described, the thermal control device 3 allows control of the temperature of the module or modules 7. As a non-limitative example, the thermal control unit 1 may be a battery pack comprising a plurality of modules 7, such as energy storage modules or cells, the temperature of which is controlled by the thermal control device 3.

Here a module 7 may be an energy storage cell. As a variant, a module 7 may comprise multiple energy storage cells. A module 7 may also be defined as a container or housing comprising one or more electronic and/or electrical components. The module 7 may be closed. It may comprise a group of cells, for example in an element forming a cover or hood over an upper part of the unit 1 or a battery pack.

The device 5, in particular for electrical storage, may comprise a housing 51 which is partially illustrated, highly schematically, in FIG. 1a or 1b or 1c and intended to receive the module or modules 7. The housing 51 may for example be generally parallelepipedic. It may be intended to be closed by a cover (not shown).

The modules 7 may be arranged in a row (FIG. 1c) or in multiple rows R1, R2 (FIGS. 1a, 1b) within the inner volume of the housing 51. These rows R1, R2 are advantageously arranged parallel with one another.

In the example of FIGS. 1a, 1b, two rows R1, R2 of modules 7 are provided. This number is not limitative; more than two rows may be provided, or a single row of modules 7 may be provided as shown on FIG. 1c. In the examples illustrated, the rows R1, R2 extend mainly along a longitudinal axis A.

Also, with reference to FIGS. 1a to 1d, the modules 7 are illustrated with a generally parallelepipedic form. This parallelepipedic form has a length, a width and a height. The modules 7 each have an upper face 71 and an opposite lower face, connected by side faces 73, 75. The upper face 71 may be intended to be arranged facing the cover (not shown) of the housing 51 containing the module or modules 7. The lower face is intended to be arranged against a bottom of the housing 51. The upper face 71 and opposite lower face extend in the length and width directions of a module 7. Two first side faces 73 are for example two large opposite side faces extending in the length and height directions of the module 7. Two second side faces 75 are for example two small opposite side faces extending in the length and height directions of the module 7. Any other form may be considered for the modules 7.

When the modules 7 are arranged in rows R1, R2, the first side faces 73 for example of adjacent modules 7 of a row R1 or R2 are arranged opposite one another. For each module 7 of a row R1 or R2, at least one of its second side faces 75 is arranged facing a wall of the housing 51. Also, at least one of the modules 7 at the end of a row R1 or R2 may be arranged with one of its first side faces 73 facing another wall of the housing 51.

One or more surfaces of the module 7 are intended to be wetted with dielectric fluid.

The surface or surfaces of a module 7 to be wetted by the dielectric fluid projected from one or more nozzles 11 (as described below) may be flat or substantially flat.

As a variant, a surface to be wetted, such as the surface of an upper face 71 of a module 7 in the orientation of FIG. 1d, maybe curved or convex, with convexity oriented towards the outside of the module 7. The curvature of this surface to be wetted facilitates a flow of the dielectric fluid to be projected from one or more nozzles 11 (as described below) towards the surfaces of the side faces 73, 75 of the module 7 which extend vertically in the example of FIG. 1d.

To this end, it is also conceivable that the surface to be wetted is inclined relative to a horizontal or vertical plane in the orientation of the thermal control unit 1 after final assembly. For example, for a surface to be wetted on the upper face 71 of the module 7, this surface may be inclined relative to the horizontal plane or to the plane defined by the opposite lower face of the module 7, and in this case the upper face 71 is not strictly perpendicular to the side faces 73, 75 of the module 7. For a surface to be wetted of a side face 73, 75 of a module 7, this surface may be inclined relative to the vertical plane, and in this case the side face 73, 75 is not strictly perpendicular to the upper face 71 and lower face of the module 7.

The invention concerns in particular the thermal control device 3 described in more detail below. It comprises a dielectric fluid circuit 9 and a predefined number of nozzles 11 for spraying the dielectric fluid.

### DIELECTRIC FLUID CIRCUIT

The dielectric fluid circuit 9 may comprise at least one element (not shown) for circulating the dielectric fluid, such as a pump. The flow of dielectric fluid in the circuit 9 may be controlled via this element such as a pump. A storage reservoir for dielectric fluid may also be provided. The circulation of the dielectric fluid is indicated by arrows F1. The dielectric fluid may be mono-phase or two-phase. The latter is selected for example depending on the phase change temperatures.

In the case of a two-phase dielectric fluid, when projected in the liquid phase, it tends to evaporate on contact with the modules 7 which are for example heated during operation. The vapour may then be cooled by a cooling circuit. In the case of a mono-phase dielectric fluid, once projected, in particular in liquid phase, the dielectric fluid may be re-aspirated by a pump for example and driven towards an exchanger (not shown) so as to be cooled before being reintroduced into the dielectric circuit 9 for thermal control of the modules 7.

The dielectric fluid circuit 9 may comprise one or more pipes 13. A pipe 13 may fluidically connect several nozzles 11. In other words, it is designed to direct the dielectric fluid towards each of the nozzles 11.

According to a particular embodiment shown on FIG. 3f, a pipe 13 may be produced by assembly of two half-shells 13A, 13B delimiting an internal channel for supply to the nozzles 11. At least one or both half-shells 13A, 13B may be made of a plastic material. The two half-shells 13A, 13B may be joined by over-molding, clipping, gluing or by ultrasound welding.

Furthermore, with reference again to FIGS. 1a to 1c, the dielectric fluid circuit 9 and more precisely the or at least one of the pipes 13 may have one or more distribution or connection points 14 for the nozzles 11. A single nozzle 11 may be connected to a distribution or connection point 14. As a variant or in addition, at least two nozzles 11 may be connected to a common distribution or connection point 14.

The dielectric fluid circuit 9 may comprise multiple parallel pipes 13 (FIG. 1a) each allowing distribution of the dielectric fluid to a respective series of nozzles 11. As a variant, a single pipe 13 (FIG. 1b or 1c) may be provided to supply all nozzles 11 in series. This variant is advantageous for example for integration in the thermal control unit 1. This variant is also more advantageous in terms of load losses.

Thus in operation, the dielectric fluid is distributed into one or more pipes 13 so as to supply the different nozzles 11. The dielectric fluid may then be projected by the nozzles 11 so as to come into contact with the surfaces to be wetted of the modules 7. At least one pipe may be provided for recovery of the dielectric fluid.

Also, the pipe 13 or at least one of the pipes 13 may be arranged so as to extend at least partly facing a row R1, R2 of modules 7, in particular above a row R1, R2 of modules 7. In the latter case, it may therefore be interposed between the modules 7 and the cover of the housing 51 containing the modules 7. It is also conceivable that the pipe 13 or at least one of the pipes 13 extends facing a space between two adjacent modules 7 or between two adjacent rows R1, R2 of modules 7. The pipe 13 or at least one of the pipes 13 may also be intended to be arranged so as to extend facing a space in the middle or substantially in the middle of one or more modules 7, or along the longitudinal or lateral edges of the module 7, or rims in the case of parallelepipedic modules 7.

The circuit 9, and in particular the pipe or pipes 13, may be fixed to a support, for example originating from a wall or the cover of the housing 51. As an alternative, the circuit 9 may integrate supports configured to be fixed to a wall or the cover of the housing 51.

### Dielectric Fluid Spray Nozzles

With respect to the nozzles 11, their number may be defined as a function of the flow of dielectric fluid or the length of the dielectric fluid circuit 9.

The nozzles 11 are intended to be arranged so as to spray dielectric fluid onto at least one surface of at least one module 7.

A surface of a module 7 to be wetted may be an upper surface, i.e. one intended to be arranged facing the cover of the housing 51. As a variant or in addition, it may be a side surface of the module 7. The surface to be wetted may be a flat or substantially flat surface, or a surface which is curved or at least partially curved.

With reference to FIGS. 2a to 2f, the nozzles 11 each comprise one or more orifices for projection of dielectric fluid. For example, the nozzle 11 or at least some nozzles 11 may have a single projection orifice so as to project a single jet of dielectric fluid, as illustrated highly schematically in FIG. 2a. As a variant or in addition, the nozzle 11 or at least some nozzles 11 may have at least two projection orifices so as to project at least two separate jets F2 of dielectric fluid, as illustrated on FIG. 2b or 2c with two jets, or on FIG. 2d or 2e with three jets, or on FIG. 2f with five jets. Naturally, these examples are purely illustrative and not limitative.

The projection orifice or orifices are in particular shaped so as to project a dielectric fluid jet F2 which is generally fan-shaped. More precisely, the shape is that of an open fan defining a circular sector or even a semicircle. The circular sector is delimited by two radii and a circle arc. The tip of the circular sector is defined by the nozzle 11. Such a jet is generally flat or in the form of a flattened cone, i.e. delimited by two main directions D1 and D2, or D1′ and D2′, or D1′ and D20′, or D1″ and D2″. These two directions DI, D2; D1′, D2′; D1′, D20′; D1″, D2″ are not mutually parallel but intersecting. More precisely, the radii defining the circular sector each extend along one of the two directions. These directions intersect at the tip of the circular sector.

The dielectric fluid jet F2 defines for example an opening angle α greater than 90°, in particular between 100° and 180°, preferably of the order of 170°. This angle α may be adapted so as to uniformly cover an entire surface to be wetted of at least one module 7 (with reference again to FIGS. 1a to 1d).

In particular, the nozzle or nozzles 11 may be configured and arranged so as to project at least one dielectric fluid jet F2 parallel to a plane defined by a surface of a module 7 to be wetted.

When a nozzle 11 is configured to project multiple dielectric fluid jets F2, these jets or at least some jets may be projected along parallel planes (as shown on FIG. 2b or 2d, or 2f) or along intersecting planes (see FIGS. 2c to 2f).

Depending on need, a nozzle 11 with multiple orifices—also called a multi-jet nozzle 11—may be configured to project several dielectric fluid jets F2 with the same or different angles For example, all jets may have the same angle α (see FIG. 2b). Alternatively, at least some jets may have the same angle α or β (see FIGS. 2d, 2f), or all jets may have different angles α, β, γ (see FIGS. 2c, 2e). The angles α, β, γ are greater than 90°, in particular between 100° and 180°. They may be adjusted to better cover the surfaces to be wetted.

When several nozzles 11 are provided, they may be identical or different, have a same or different number of projection orifices, or be configured to project dielectric fluid jets in parallel or non-parallel planes. The various nozzles 11 may be arranged with identical or substantially identical orientation, or in mirror symmetry, or in variable orientations relative to the modules 7 or a pipe 13 of the dielectric fluid circuit 9.

FIG. 3a shows an exemplary embodiment of a nozzle 11, in particular comprising a nozzle head 15 fitted with a projection orifice. In this example, the projection orifice is formed by a projection slot 17. The contour of such a projection slot 17 may be generally oval in shape.

The nozzle 11 may comprise a projection channel 19 in which dielectric fluid originating from a pipe of the dielectric fluid circuit is intended to flow. The projection channel 19 may extend mainly along a longitudinal axis L.

Advantageously, the nozzle 11 and in particular the nozzle head 15 may be equipped with at least one dielectric fluid deflector 21 facing an outlet 191 of the projection channel 19. Such a deflector 21 is shaped so as to orient the dielectric fluid to create the generally flat or fan-shaped jet.

For example, the deflector 21 comprises a wall 211 inclined relative to the longitudinal axis L of the projection channel 19. This inclined wall 211 extends so as to form an obstacle facing the outlet 191 of the projection channel 19.

Preferably, the connecting angles between different parts of the nozzle head 15 are not sharp.

Thus the nozzle head 15 advantageously comprises a generally rounded shape between the outlet 191 of the projection channel 19 and the inclined wall 211 of the deflector 21. The rounded shape supports the dielectric fluid as it leaves the projection channel 19 and may thus increase the maximum flow for a given size of projection channel 19. According to a very particular and non-limiting example, this rounding may have a radius ρ which may be of the order of 0.5 mm to 3 mm.

As most clearly visible on FIG. 3b, the inclined wall 211 forms an obtuse angle θ with the longitudinal axis L of the projection channel 19. This angle θ may for example lie between 105° and 130°.

Furthermore, the inclined wall 211 may have a height h which increases along an axis T transverse to the longitudinal axis L of the projection channel 19 (see FIG. 3c). The maximum height hmax may equal at least half the height of the projection channel 19. Preferably, said maximum height hmax is equal at most to 150% of the height of the projection channel 19. According to a very particular and non-limiting example, this maximum height hmax may be of the order of 4 mm to 5 mm.

The deflector 21 may also comprise an outer wall 213 extending transversely relative to the longitudinal axis L of the projection channel 19 and connecting the free end of the inclined wall 211 with the rest of the nozzle head 15.

Also, with reference to FIGS. 3d and 3e, the outlet 191 of the projection channel 19 may widen relative to the rest of the projection channel 19, for example forming a main section 193 of the projection channel 19. The nozzle head 15 may thus have a so-called opening wall 25 delimiting the outlet 191 of the projection channel 19.

Preferably, this opening wall 25 has an opening angle Ω greater than 90°, such that when projected by the nozzle 11, the dielectric fluid jet has a widened and flattened form, for example an oval or flattened conical form, allowing thermal control or cooling of a large surface area wetted by this jet. The opening angle Ω may for example lie between 100° and 170° to 180°, in particular of the order of 120° to 130°.

The nozzle head 15 advantageously comprises a generally rounded shape between the opening wall 25, delimiting the outlet 191 of the projection channel 19, and an inner wall 27 delimiting the main section 193 of the projection channel 19. According to a very particular and non-limiting example, this rounding may have a radius σ which may be of the order of 0.5 mm to 2 mm.

Advantageously, one or more parameters of a nozzle 11, according to the example in FIGS. 3a to 3e, may be modified so as to adapt the dielectric fluid jet to requirements. Thus the section of the projection channel 19 may be modified to adapt the flow of dielectric fluid to be projected by the nozzle 11. The angle θ formed between the inclined wall 211 of the deflector 21 and the longitudinal axis L of the projection channel 19 may be modified for example to wet a different surface. The radius ρ of the rounding between the inclined wall 211 of the deflector 21 and the outlet 191 of the projection channel 19 may be adapted so as to reduce the load loss. The opening angle Ω at the outlet 191 of the projection channel 19 may be adapted so as to wet a larger or smaller surface. The radius σ of the opening wall 25 delimiting the outlet 191 of the projection channel 19 may be adjusted so as to improve the opening of the dielectric fluid jet to be projected by the nozzle 11. Finally, the height h of the deflector 21 may be adapted so as to improve the precision of the dielectric fluid jet to be projected by the nozzle 11.

According to an alternative, the deflector may not be integrated in the nozzle 11. For example, one or more nozzles 11 may be arranged so to project a dielectric fluid jet at least partially onto a housing wall which then forms the deflector. Such a wall would allow deflection of at least part of the jet towards a surface of one or more modules 7. The wall forming the deflector may for example be the cover (not shown) of the housing 51. In other words, the nozzle or nozzles 11 would be arranged so as to project a dielectric fluid jet at least partially onto the cover. According to another variant, the wall forming the deflector could be a side wall of the housing 51. In other words, the nozzle or nozzles 11 would be arranged so as to project a dielectric fluid jet at least partially towards such a side wall.

Advantageously, one or more nozzles 11 could be implemented with a pipe 13.

In the example illustrated on FIG. 3f of a pipe 13 produced by joining two half-shells 13A, 13B, the nozzles 11—for example of plastic and in particular polymer—could be formed in at least one of the molded half-shells 13B, for example by injection-molding. In the example illustrated, the nozzles 11 are integrated in one and the same face of the half-shell 13B. It is also possible to integrate nozzles 11 in several faces of the half-shell 13B, which would allow the dielectric fluid to be sprayed in several directions.

As an alternative, the nozzles 11 may be separate from the pipe 13 and be fluidically connected at the distribution or connection points 14 of the pipe 13. In this case, the nozzles 11 could for example be metallic. The nozzles 11 may for example be screwed, clipped and/or also inserted, mounted by adaptation, in a pipe 13.

Also, one or more nozzles 11 may be intended to be arranged between at least two modules 7. More precisely, the nozzle or nozzles 11 may be arranged facing a space between two modules 7, and in particular above a space between the upper faces 71 of two adjacent modules 7 as shown in FIGS. 1a to 1d. On final assembly of the thermal control unit 1, such nozzles 11 above the space between the upper faces 71 of two adjacent modules 7 would then be interposed between the cover (not shown) of the housing 51 and the modules 7 received in the housing 51.

The dimensions of the nozzles 11, in particular their height, may be adapted according to the internal space of the housing 5, in particular between the modules 7 and any cover.

Such nozzles 11 may be arranged centrally or substantially centrally relative to the adjacent modules 7. More precisely, these nozzles 11 may be arranged centrally or substantially centrally relative to the opposing edges or rims of two adjacent modules 7, which may be longitudinal or alternatively lateral edges.

Alternatively or additionally, one or more nozzles 11 may be arranged facing a space between at least one module 7 and a wall of the housing 51. In particular, this is a side wall of the housing 51 facing a side face 73 or 75 of the module 7 (FIGS. 4a to 6b). Such nozzles 11 may be arranged centrally relative to an edge or rim of the module 7, which may be a longitudinal or lateral edge, facing the wall of the housing 51. According to another example, such nozzles 11 may be arranged facing a space between the tip of the module 7 and the wall of the housing 51.

According to another variant or in addition, one or more nozzles 11 may be intended to be arranged facing a space between at least two opposing tips of two adjacent modules 7 (FIGS. 4c to 6b).

It is also conceivable to arrange one or more nozzles 11 facing a space between two rows R1, R2 of modules 7. Such nozzles 11 may be arranged facing a space between two opposing tips of a module 7 in one of the rows, e.g. R1, and of another module 7 in the adjacent row of modules 7, e.g. R2.

Also, the nozzles 11 may be arranged in series along the dielectric fluid circuit 9, more precisely along at least one pipe 13 (FIGS. 1b, 1c, 4a). As a variant, at least some nozzles 11 may be supplied in parallel.

Several series of nozzles 11 may be provided. The series of nozzles 11 may have a same or a different number of nozzles 11. The series of nozzles 11 generally extend parallel to one another. The series of nozzles may be supplied in series (FIGS. 1b, 4a) or alternatively in parallel (FIGS. 1a, 4c, 5a, 6a). Each series comprises one or more nozzles 11.

In the case of one or more rows R1, R2 of modules 7 to be thermally controlled, at least one series of nozzles 11 may be associated with each row R1, R2 of modules 7 (FIGS. 1a, 1b, 4a to 6b). Several series of nozzles 11 may be associated with a row R1, R2 of modules 7. As a variant or in addition, at least one series of nozzles 11 may be arranged facing a space between two rows of modules 7 (FIGS. 4c to 6b).

### Arrangement Strategies

Various strategies or configurations for arranging the nozzles 11 relative to the modules 7 are conceivable.

### First Configuration

According to a first configuration, examples of which are shown in FIGS. 1a to 1d, at least one nozzle 11 is arranged facing the space between two adjacent modules 7. More precisely, such a nozzle 11 may be situated above the space between the upper faces 71 of two adjacent modules 7.

The pipes 13 extend at least partially parallel to a row R1, R2 of modules 7, i.e. along the longitudinal axis A of the row R1, R2. According to the particular examples illustrated in FIGS. 1a to 1c, the pipes 13 extend at least partially parallel to the side edges of the modules 7.

The nozzles 11 allow projection of a generally flat or fan-shaped jet F2 of dielectric fluid which at least partially wets the surfaces, e.g. the upper faces 71, of two adjacent modules 7. These surfaces, in particular the upper faces 71, intended to be at least partially wetted by the dielectric fluid, may be curved or inclined as described above.

In the examples illustrated, the nozzles 11 are oriented so as to project a dielectric fluid jet F2 parallel to the plane defined by the surfaces to be wetted, here the upper faces 71 of the modules 7. To do this, the projection orifices of the nozzles 11 are for example oriented towards the side walls of the housing 51 facing the two side faces 75. With reference to the orientation of the elements in FIGS. 1a, 1b, 1c, 1d, the dielectric fluid jet F2 is horizontal.

Furthermore, the nozzle 11 or each nozzle 11 is for example arranged centrally relative to the modules 7, more precisely centrally relative to the longitudinal edges of the modules 7.

This first configuration allows an even spray of dielectric fluid onto the modules 7, in particular their upper faces 71. Also, the first configuration allows the projected dielectric fluid to better reach the spaces between the modules 7.

The nozzles 11 are advantageously arranged such that the modules 7 can be wetted by at least two generally flat or fan-shaped jets F2 of dielectric fluid. In the example illustrated, the surfaces of the upper faces 71 of two adjacent modules 7 are intended to be at least partly wetted by two dielectric fluid jets F2. With reference to the orientation of the elements in FIGS. 1a to 1c, the two dielectric fluid jets F2 are horizontal.

A single, preferably multi-jet nozzle 11 may be integrated in or connected to different distribution or connection points 14 of the pipe 13. The multi-jet nozzle 11 advantageously comprises two projection orifices as illustrated in FIG. 2b, so as to project the two dielectric fluid jets F2 with a same opening angle α. As a variant, the opening angles may be different in some cases.

As a variant or in addition, nozzles 11 may be integrated in or connected in pairs to different common distribution or connection points 14. They each comprise a single projection orifice as illustrated in FIG. 2a. The nozzles 11 of a pair may be arranged mirror-symmetrically relative to the pipe 13 and oriented so as to project two complementary jets F2 of dielectric fluid in order to optimize the wetting of the modules 7.

The number of nozzles 11 may be selected such that each module 7 is intended to be wetted by the dielectric flow F2 projected by a nozzle 11 or an associated pair of nozzles 11. In the particular examples of FIGS. 1a to 1c, a nozzle 11 is not provided between each pair of modules 7. For example, for a given row R1, R2 of modules 7, a nozzle 11 and or a pair of nozzles 11 may be arranged facing one inter-module space out of two. This arrangement is economic with regard to the number of nozzles 11.

Naturally, a variant embodiment with at least one nozzle 11 or a pair of nozzles 11 facing the space between each pair of modules 7 is conceivable.

The first configuration may apply equally well to a device 5 with only a single row of modules 7 (FIG. 1c) and to a device 5 with several rows R1, R2 of modules 7 (FIGS. 1a, 1b).

This configuration may also apply equally well to a series supply of the set of nozzles (FIGS. 1b, 1c) and to a parallel supply of a respective series of nozzles 11 for each row R1, R2 of modules 7 (FIG. 1a).

### Second Configuration

Exemplary arrangements of the nozzles 11 according to a second configuration are shown on FIGS. 4a to 4d. Only differences with respect to the first configuration are detailed below.

According to the second configuration, at least one nozzle 11 is arranged facing the space between each pair of modules 7. The modules 7 may be arranged in one or more rows R1, R2 of modules 7.

The nozzles 11 are therefore arranged facing each inter-module space of a row R1, R2 of modules 7. This allows better wetting of the side surfaces of the modules 7, in particular the opposing first side surfaces 73 of two adjacent modules 7. As before, one or more surfaces to be wetted may be curved or inclined.

Several nozzles 11 may be integrated in or fluidically connected to a common distribution or connection point 14, or a single multi-jet nozzle 11 may be integrated in or fluidically connected to a given distribution or connection point 14. The nozzles 11 may be similar to the first configuration.

Advantageously, at least some nozzles 11 are arranged such that the modules 7 can be wetted by at least three generally flat or fan-shaped jets F2 of dielectric fluid.

Two dielectric fluid jets F2 are intended to at least partially wet the surfaces, e.g. the upper faces 71, of two adjacent modules 7. For this, the corresponding projection orifices of the nozzles 11, allowing projection of these two dielectric fluid jets F2, are for example oriented towards the side walls of the housing 51 facing the two side faces 75. With reference to the orientation of the elements in FIGS. 4a to 4b, these two dielectric fluid jets F2 are horizontal.

A third dielectric fluid jet F2 is intended to at least partially wet a surface of the opposing first side faces 73 of two adjacent modules 7. The third dielectric fluid jet F2 is intended to be projected parallel to the plane defined by the opposing first side faces 73 of adjacent modules 7. For this, the corresponding projection orifice is for example oriented towards the bottom or a lower wall of the housing 51. With reference to the orientation of the elements in FIG. 4b, this third dielectric fluid jet F2 is vertical. This third jet reinforces the wetting of the side faces, in particular the first side faces 73 of the modules 7.

In other words, if the nozzle 11 is a multi-jet nozzle 11, it advantageously comprises three projection orifices as illustrated in FIG. 2d, so as to project the three jets F2 of dielectric fluid with a same opening angle or with one or more different opening angles α, β.

Alternatively, three nozzles 11, each with a single projection orifice as illustrated in FIG. 2a, may be fluidically connected to the same distribution or connection point 14. Two of these nozzles 11 may be arranged mirror-symmetrically relative to the pipe 13, similarly to the first configuration, so as to project two dielectric fluid jets F2 parallel to the upper faces 71 of the modules 7. The third nozzle 11 may be arranged so as to project the third dielectric fluid jet F2 parallel to the first side faces 73 of the modules 7. It could also be considered to provide one nozzle 11 for projecting a single jet and another nozzle 11 for projecting two jets.

Also, as shown in the examples of FIGS. 4a to 4d, at least one other nozzle 11 may be arranged facing a space between at least one module 7, in particular a module 7 at the end of a row R1, R2 of modules 7, and a wall of the housing 51. In particular, this is the wall facing a first side face 73 of the end module 7. With reference to the orientation of the thermal control unit 1 after final assembly, such a nozzle 11 would be situated above this space. Such a nozzle 11, in the example illustrated in FIG. 4a, is arranged centrally relative to a longitudinal edge of the end module 7 facing the wall of the housing 51. It may be arranged so as to project at least one dielectric fluid jet F2 parallel to the first side face 73 of the module 7. The corresponding projection orifice is for example oriented towards the bottom or a lower wall of the housing 51, i.e. opposite the cover. Such a jet is vertical with reference to the orientation of elements in FIGS. 4b and 4d.

According to an example not shown, it is also possible that one or more nozzles 11 are arranged so as to spray the first side faces 73 of the modules 7 at the other end of each row R1, R2 of modules 7.

Naturally, this variant with one or more nozzles 11 between an end module 7 and a wall of the housing 51 may also apply to the exemplary embodiments of the first configuration.

With reference to FIGS. 4c and 4d, one or more additional nozzles 11 may also be arranged facing a space between at least two opposing tips of two adjacent modules 7 of a row R1 or R2.

For example, these may be the tips nearest to another wall of the housing 51, in this example that facing the second side faces 75 of the modules 7. These nozzles 11 are thus arranged facing the space between one or more modules 7 and this wall of the housing 51.

These additional nozzles 11 may be aligned with the nozzles 11 arranged facing the inter-module spaces of a row R1, R2 of modules 7 as described above. They may be arranged so as to project at least one dielectric fluid jet F2 parallel to a second side face 75 of a module 7. The corresponding projection orifice is for example oriented towards the bottom of the housing 51. Such a jet is vertical with reference to the orientation of elements in FIG. 4d.

At least one such nozzle 11 may be arranged at one inter-module space out of two for example, or at each inter-module space.

Thus the side faces 73 and 75 facing a respective wall of the housing 51 may be sprayed by dielectric fluid jets F2.

This variant with one or more additional nozzles 11 between at least two opposing tips of two adjacent modules 7 of a row R1, R2 may also apply to the exemplary embodiments of the first configuration.

Also, in the example illustrated with parallelepipedic modules 7, some nozzles 11 may be arranged facing the space between two tips on either side of the opposing rims, for example the longitudinal rims, of two adjacent modules 7. In this case, one or more additional nozzles 11 are arranged between two adjacent rows R1, R2 of modules 7. At least one pipe 13 then extends between the two rows R1, R2 of modules 7. This pipe 13 extends parallel to the longitudinal axis A of the rows R1, R2.

Such nozzles 11 may be arranged facing a space between the opposing tips of two modules 7 in a first row R1 and of two other modules 7 in an adjacent second row R2.

These nozzles 11 may be aligned with the nozzles 11 arranged centrally facing the inter-module spaces of each row R1, R2 of modules 7. They may be arranged so as to project at least one dielectric fluid jet F2 parallel to opposing second side faces 75 of modules 7 of the two rows R1 and R2. Such a jet is vertical with reference to the orientation of elements in FIG. 4d.

At least one such nozzle 11 may be arranged at one inter-module space out of two for example, or at each inter-module space. Thus all side faces 73 and 75 may be sprayed by dielectric fluid jets F2.

This variant may also apply to the exemplary embodiments of the first configuration.

Either one of the variant embodiments or a combination of variants of this second configuration may apply equally well for series supply of the set of nozzles 11 and for parallel supply of the respective series of nozzles 11 for each row R1, R2 of modules 7.

### Third Configuration

Exemplary arrangements of the nozzles 11 according to a third configuration are shown on FIGS. 5a to 5b. Only differences with respect to the second configuration are detailed below. Common characteristics are not described again.

In contrast to the second configuration, the third configuration does not necessarily comprise nozzles 11 arranged centrally relative to two adjacent modules 7.

According to the third configuration, one or more nozzles 11 are arranged facing a space between at least two opposing tips of two adjacent modules 7 of a row R1, R2. The modules 7 may be arranged in one or more rows of modules 7. More precisely, in the example illustrated with parallelepipedic modules 7, at least two nozzles 11 are arranged facing the space between the tips on either side of opposing rims, for example longitudinal rims, of two adjacent modules 7.

Such nozzles 11 are advantageously arranged between each pair of modules 7. According to a variant not shown, the nozzles 11 may not be arranged between each pair of modules 7, but for example could be provided for one space out of two.

When the modules 7 are arranged in several rows R1, R2, some of these nozzles 11 are arranged between two rows R1 and R2 of modules 7.

Also, similarly to the second configuration, at least one other nozzle 11 may be arranged between at least one end module 7 and a wall of the housing 51, in particular that facing a first side face 73 of the end module 7. At least one other nozzle 11 may be arranged on the opposite side facing the first side face 73 of the other end module 7 of a row R1 or R2.

One or more nozzles 11 may be similar to the first configuration or second configuration. Thus at least some nozzles 11 may be configured to project a single, generally flat or fan-shaped jet F2 of dielectric fluid. As a variant or in addition, at least some nozzles 11 may be configured to project several generally flat or fan-shaped jets F2 of dielectric fluid, for example two, three, four or even five dielectric fluid jets F2. The exemplary nozzles 11 configured to project a single jet, two jets or three jets F2 of dielectric fluid, and the orientation of such jets, have already been described and are not described again here.

An example with five dielectric fluid jets F2 is described below. Two dielectric fluid jets F2 may be intended to at least partially wet the surfaces, e.g. the upper faces 71, of two adjacent modules 7. The corresponding projection orifices are for example oriented towards the modules 7. With reference to the orientation of the elements in FIGS. 5a to 5b, these two dielectric fluid jets F2 are horizontal. A third and a fourth dielectric fluid jet F2 are intended to at least partially wet a surface of the opposing first side faces 73 of two adjacent modules 7. They are projected parallel to the plane defined by the first side faces 73 of the modules 7. The corresponding projection orifices are for example oriented towards the bottom of the housing 51. With reference to the orientation of the elements in FIG. 5b, the third and fourth dielectric fluid jets F2 are vertical. A fifth dielectric fluid jet F2 is intended to at least partially wet a surface of the opposing second side faces 75 of two modules 7 of two respective rows R1 and R2. The corresponding projection orifice is for example oriented towards the bottom of the housing 51. With reference to the orientation of the elements in FIG. 5b, this fifth dielectric fluid jet F2 is vertical.

In other words, if the nozzle 11 is a multi-jet nozzle 11, it advantageously comprises five projection orifices as illustrated in FIG. 2f, so as to project the five dielectric fluid jets F2 with a same opening angle or with one or more different opening angles α, β, γ.

Alternatively, one or more nozzles 11, each comprising a single projection orifice as illustrated in FIG. 2a, may be integrated in or fluidically connected to the same distribution or connection point 14, and one or more other nozzles 11, each comprising at least two projection orifices as illustrated in FIGS. 2b to 2e, may be connected to this same distribution or connection point 14.

According to the particular example of FIGS. 5a, 5b, the nozzles 11 arranged between two rows R1 and R2 of modules 7 allow at least partial wetting of the modules 7 by five generally flat or fan-shaped jets F2 of dielectric fluid. At least some nozzles 11 arranged between the modules 7 and the wall of the housing 51 facing the second side faces 75 allow wetting of the modules 7 by at least two dielectric fluid jets F2. As a variant or in addition, at least some nozzles 11 arranged between the modules 7 and the wall of the housing 51 facing the second side faces 75 allow wetting of the modules 7 by at least three dielectric fluid jets F2. The nozzles 11 arranged facing the end modules 7 allow at least partial wetting of the end modules 7 by at least one generally flat or fan-shaped jet of dielectric fluid F2.

The third configuration thus proposes jets which are arranged both horizontally and vertically between the modules 7, between the rows R1, R2 of modules 7, at the spaces between the modules 7 and the housing 51, which allows more targeted wetting in particular of the side surfaces 73, 75 of the modules 7 by the dielectric fluid jets F2.

Either one of the variant embodiments or a combination of variants of this third configuration may apply equally well for series supply of the set of nozzles 11 and for parallel supply of the respective series of nozzles 11 for each row R1, R2 of modules 7.

### Fourth Configuration

Exemplary arrangements of the nozzles 11 according to a fourth configuration are shown on FIGS. 6a and 6b. Only differences with respect to the first configuration are detailed below.

According to this fourth configuration, at least one nozzle 11, 11a, 11b is arranged facing and in particular above a space between two adjacent modules 7, being fluidically connected to a pipe 13 extending in the width direction of a row R1, R2 of modules 7, i.e. along an axis B. This axis B is transverse to the longitudinal axis A of a row R1, R2. The pipe 13 in this example extends perpendicularly to a row R1, R2 of modules 7. It extends parallel to the longitudinal edges or rims of the modules 7.

The modules 7 may be arranged in one or more rows R1, R2 along the longitudinal axis A. In the text below, a string of modules 7 designates at least two modules 7 aligned along the transverse axis B. In the example illustrated in FIG. 6a, four strings S1, S2, S3, S4 of modules 7 are shown. Naturally, this number is not limitative.

At least one common pipe 13 may extend between the modules 7 of several adjacent rows R1, R2, and more particularly between two consecutive strings S1, S2, S3, S4 of modules 7.

Also, at least two groups of nozzles may be arranged on either side of the module 7 or a string S1-S4 of modules 7. To facilitate perception and understanding of the example illustrated in FIGS. 6a and 6b, the nozzles of a first group carry reference 11a and are also described as “first nozzles”, and the nozzles of a second group carry reference 11b and are also described as “second nozzles”. The first and second nozzles 11a, 11b may be similar to or different from the nozzles 11 described above.

The second nozzles 11b are not aligned with the first nozzles 11a along the longitudinal axis A of a row R1, R2. The first nozzles 11a may be aligned with one another, and the second nozzles 11b may also be aligned with one another along the longitudinal axis A.

It is conceivable that the first nozzles 11a associated with a string, e.g. S3, of modules 7 are aligned with second nozzles 11b associated with a different string, e.g. S4, of modules 7, and so on.

The first nozzles 11a are oriented so as to project at least one dielectric fluid jet F2 in a first direction, and the second nozzles 11b are oriented so as to project at least one dielectric fluid jet F2 in a second direction opposite the first direction.

Thus the first and second nozzles 11a, 11b are staggered so as to wet at least one surface of one or more modules 7. Such an arrangement is more advantageous in terms of homogeneity,

In the example illustrated on FIGS. 6a, 6b, the first and second nozzles 11a, 11b allow wetting of the upper face 71 of several modules 7. Naturally, such an arrangement also applies to the configuration of modules 7 in a single row.

Furthermore, when the modules 7 are arranged in several rows R1, R2, the nozzles of one of the groups, e.g. the second nozzles 11b, may be arranged between two rows R1, R2.

According to the particular example of FIG. 6a, 6b, the first and second nozzles 11a, 11b may be configured to each project at least one generally flat or fan-shaped jet F2 of dielectric fluid intended to at least partially wet a surface of the upper faces 71 of the modules 7. The corresponding projection orifices are for example oriented towards a series of modules 7. With reference to the orientation of the elements in FIGS. 6a, 6b, this dielectric fluid jet F2 is horizontal.

Alternatively, at least some first and second nozzles 11a, 11b may be configured to each project two generally flat or fan-shaped jets F2 of dielectric fluid. A first dielectric fluid jet F2 may be intended to at least partially wet the surfaces of the upper faces 71 of the modules 7. This is a horizontal jet as described above. A second dielectric fluid jet F2 is intended to at least partially wet a surface of the opposing first side faces 73 of the modules 7. This second jet is projected parallel to the plane defined by the first side faces 73 of the modules 7. The corresponding projection orifice is for example oriented towards the bottom of the housing 51. With reference to the orientation of the elements in FIG. 6b, the second dielectric fluid jet F2 is vertical.

Also, at least one nozzle 11 may be arranged facing and in particular above a space between at least one end module 7 and a wall of the housing 51. In particular, this is the wall facing a first side face 73 of the end module 7. This nozzle 11 is more precisely arranged facing a space between at least two opposing tips of two adjacent modules 7 of an end string, for example here S4. The nozzle 11 may be arranged so as to project at least one dielectric fluid jet F2 parallel to the first side faces 73 of the modules 7. Such a jet is vertical with reference to the orientation of elements in FIGS. 6a and 6b.

One or more nozzles 11 may be arranged so as to spray the first side faces 73 of the modules 7 at the other end, for example here one or more modules 7 of string S1. Such a nozzle 11 in the example illustrated is arranged centrally relative to a longitudinal edge of the end module 7.

As a variant or additionally, at least one other nozzle 11 may be arranged facing a space between at least one module 7 and the wall of the housing 51 facing the two side faces 75 of a row R1, R2 of modules 7. With reference to the orientation of the thermal control unit 1 after final assembly, such a nozzle 11 would be situated above this space. The nozzle 11 may be arranged so as to project at least one dielectric fluid jet F2 parallel to the second side faces 75 of the modules 7. The corresponding projection orifice is for example oriented towards the bottom of the housing 51. Such a jet is vertical with reference to the orientation of elements in FIGS. 6a and 6b.

At least some nozzles 11, 11a, 11b may be configured to project a single generally flat or fan-shaped jet F2 of dielectric fluid. As a variant or in addition, at least some nozzles 11 may be configured to project several generally flat or fan-shaped jets F2 of dielectric fluid, for example two dielectric fluid jets F2.

In particular, the first and second nozzles 11a, 11b—if multi-jet nozzles—advantageously comprise two projection orifices so to project the two dielectric fluid jets F2 with a same opening angle or with different opening angles. Alternatively, at least two nozzles 11a, 11b, each comprising a single projection orifice, may be fluidically connected to a same distribution or connection point 14 so as to be able to project the two dielectric fluid jets F2.

### Fifth Configuration

Exemplary arrangements of the nozzles 11 according to a fifth configuration are shown on FIG. 7. Only differences with respect to the first configuration are detailed below.

In contrast to the first configuration, the fifth configuration does not necessarily comprise nozzles 11 arranged centrally relative to the space between two adjacent modules 7.

In this example, at least one nozzle 11 may be arranged facing and in particular above a space between at least one module 7 and a wall of the housing 51. In particular, this is a side wall of the housing arranged facing the two side faces of a row R1, R2 of modules 7.

Such a nozzle 11 may thus also be arranged facing a space between the opposing tips of two adjacent modules 7 of a row R1 or R2, these tips being arranged next to the housing wall 51.

At least one such nozzle 11 may be arranged at one inter-module space out of two for example, or at each inter-module space, as in the example shown on FIG. 7.

As a variant or in addition, at least one nozzle 11 may be arranged between a module 7 at the end of a row R1, R2 and the wall of the housing 51, in this example the side wall facing the two side faces of the modules 7.

One or more nozzles 11 may be similar to the nozzles 11 described above. Thus at least some nozzles 11 may be configured to project a single dielectric fluid jet F2. This may be for example a vertical dielectric fluid jet, parallel to a side face of the module 7. As a variant or in addition, at least some nozzles 11 may be configured to project several dielectric fluid jets F2.

The or each nozzle 11 may be arranged so as to project at least one generally flat or fan-shaped jet F2 of dielectric fluid in the direction of the modules 7. To do this, the or at least one projection orifice of such a nozzle 11 is oriented towards the modules 7, more precisely so as to face a space between two adjacent modules 7 of a row.

At least part of the dielectric fluid jet F2 projected by a nozzle 11 may at least partially wet a second side face of the module 7 facing the wall of the housing 51. The dielectric fluid jet F2 projected by the nozzle 11 may also wet a first side face of the module 7.

Advantageously, at least part of the dielectric fluid jet F2 projected by a nozzle 11 may reach the cover and be deflected thereby. This creates a spread of the jet over a surface area, here the upper face 71, of at least one module 7 which is larger than the area of the cover wetted by the initial dielectric fluid jet F2.

As a variant or in addition, in particular at an end module 7, part of the dielectric fluid jet F2 projected by a nozzle 11 may also be deflected by the wall of the housing facing the end module 7. A spread jet can then wet a larger surface area of the first side wall of the end module 7.

Thus the thermal control device 3 offers a system of nozzles 11, 11a, 11b allowing dielectric fluid to be sprayed over different surfaces of the modules 7, contributing to a more uniform thermal control, in particular cooling, of these modules 7 than in the solutions from the prior art. In particular, the dielectric fluid may be sprayed uniformly even if the modules 7 are arranged sloping for example relative to the horizontal in a vehicle.

In particular, the generally flat or flattened or fan-shaped jet or jets F2 of dielectric fluid, also described as planar jets, may be projected by the nozzles 11, 11a, 11b with a wider and longer spread than conventional conical jets, which allows them to cover a larger surface area of the modules 7 to be wetted. Such flat jets may thus reach the surfaces of the modules 7 to be wetted irrespective of the slope or location of the modules 7. One or more parameters of the nozzles 11, 11a, 11b may be adjusted to further optimize the projected jet F2 of dielectric fluid.

Furthermore, when the nozzles 11, 11a, 11b are multi-jet nozzles, the number of nozzles 11, 11a, 11b may be reduced, lowering the cost of the control device 3, while allowing a homogenous spray of dielectric fluid onto the surfaces of the modules 7.

Also, according to the various strategies or configurations described above, the arrangement of the nozzles 11, 11a, 11b is designed for an even spray of dielectric fluid over the surfaces of the modules 7. In particular, these arrangements bring an improvement in the thermal control, such as cooling, of the upper surfaces 71, but also of the side surfaces 73, 75 of the modules in order to ensure an even cooling of the modules 7.

1. A thermal control device for at least one module comprising at least one electronic and/or electrical component, for a motor vehicle,
the thermal control device comprising a dielectric fluid circuit and a predefined number of nozzles for spraying dielectric fluid and configured to be arranged so as to wet at least one surface of the at least one module with dielectric fluid,
wherein the spray nozzles are configured to project, via at least one projection orifice, a fan-shaped jet of dielectric fluid delimited by two main directions,
the spray nozzles each comprising:
a projection channel configured to direct the dielectric fluid flowing, and
at least one dielectric fluid deflector onto which the projection channel opens, so as to orient the dielectric fluid in order to create the fan-shaped jet.

2. The device as claimed in claim 1,
wherein the projection orifice is formed by a projection slot.

3. The device as claimed in claim 2,
wherein the projection channel extends mainly along a longitudinal axis, and
wherein the deflector comprises a wall which is inclined relative to the longitudinal axis and extends so as to form an obstacle facing an outlet of the projection channel.

4. The device as claimed in claim 3,
wherein the inclined wall of the deflector forms an angle between 105° and 130° with the longitudinal axis of the projection channel.

5. The device as claimed in claim 3,
wherein the inclined wall of the deflector extends over a height which increases along an axis transverse to the longitudinal axis of the projection channel up to a maximum height of at least half the height of the projection channel and at most 150% of the height of the projection channel.

6. The device as claimed in claim 1, comprising at least two series of spray nozzles,
wherein the dielectric fluid circuit comprises at least two parallel pipes for supplying the two series of spray nozzles.

7. A thermal control unit for a motor vehicle, the thermal control unit comprising:
at least one module comprising at least one electronic and/or electrical component, and
at least one device for thermal control of the at least one module as claimed in claim 1.

8. The thermal control unit as claimed in claim 7 comprising a plurality of modules,
wherein the at least one device comprises at least one spray nozzle arranged facing a space between two adjacent modules.

9. The thermal control unit as claimed in claim 7,
wherein the at least one device comprises at least two groups of spray nozzles arranged such that the spray nozzles of a first group are oriented so as to project at least one dielectric fluid jet in a first direction, and the spray nozzles of a second group are oriented so as to project at least one dielectric fluid jet in a second direction opposite to the first direction.
